(19) United States
(12) Patent Application Publication
(10) Pub. No.: US 2009/0242397 A1
(43) Pub. Date: Oct. 1, 2009

(54) SYSTEMS FOR CONTROLLING CATHODIC ARC DISCHARGE

(75) Inventor: Scott Andrew Weaver, Ballston Lake, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 12/059,036

(22) Filed: Mar. 31, 2008

(51) Int. Cl. C23C 14/00

(52) U.S. Cl. 204/298.41

(57) ABSTRACT

A system for controlling cathodic arc discharge is provided. The system includes a vacuum chamber forming an anode. The system also includes a power supply connected to the vacuum chamber, wherein the power supply is configured to generate an electric field within the vacuum chamber. The system further includes a cathode disposed within the vacuum chamber. The system also includes at least one permanent magnet configured to actuate in a translational direction inwards and outwards of the cathode, wherein the magnet is further configured to apply a magnetic field in a direction perpendicular to a face of the cathode and to the electric field to bum the cathode at a predetermined radius on the face of the cathode.

### BACKGROUND

The invention relates generally to vapor deposition systems and more specifically, to cathodic arc vapor deposition systems

Cathodic vapor deposition typically involves a source material and a substrate to be coated placed in an evacuated deposition chamber. The chamber contains only a relatively small amount of gas. A negative lead of a direct current (DC) power supply is attached to the material to be evaporated (hereinafter referred to as the “cathode”) and a positive lead is attached to an anodic member (hereinafter referred to as the chamber). An arc-initiating trigger, at or near the same electrical potential as the anode, contacts the cathode and subsequently moves away from the cathode. When the trigger is still in close proximity to the cathode, the difference in electrical potential between the trigger and the cathode causes an arc of electricity to extend there between. As the trigger moves further away, the existing potential between the cathode and chamber causes an arc to develop and stay on the cathode. The exact point, or points, where an arc touches the surface of the cathode is referred to as a cathode spot.

Absent a steering mechanism, a cathode spot will move randomly about a surface of the cathode. The energy deposited by the arc at a cathode spot is intense; on the order of 10⁵ to 10⁷ amperes per square centimeter with a duration of a few to several microseconds. The intensity of the energy raises the local temperature of the cathode spot to approximately equal that of the boiling point of the cathode material. As a result, cathode material at the cathode spot vaporizes into a plasma containing atoms, molecules, ions, electrons, and particles. Positively charged ions liberated from the cathode are attracted towards the substrate or a workpiece within the deposition chamber having a negative electrical potential relative to the positively charged ion. Some deposition processes maintain the substrate to be coated at the same electrical potential as the anode. Other processes use a biasing source to lower the potential of the substrate and thereby make the substrate relatively more attractive to the positively charged ions. In either case, the substrate becomes coated with the vaporized material liberated from the cathode. The random movement of the arc leads to a non-uniform erosion of the cathode, thus limiting useful life of the cathode.

Accordingly, there is a need for an improved cathodic arc deposition system and specifically, there is a need for an improved steering mechanism for the electric arc.

### BRIEF DESCRIPTION

In accordance with an embodiment of the invention, a system for controlling cathodic arc discharge is provided. The system includes a vacuum chamber forming the anode. The system also includes a power supply connected to the vacuum chamber, wherein the power supply is configured to generate an electric field within the vacuum chamber. The system further includes a cathode disposed within the vacuum chamber. The system also includes at least one permanent magnet configured to actuate in a translational direction inwards and outwards of the cathode. The magnet is further configured to apply a magnetic field in a direction perpendicular to a face of the cathode and to the electric field to burn the cathode at a predetermined radius on the face of the cathode.

In accordance with another embodiment of the invention, a system for controlling cathodic arc discharge is provided. The system includes a vacuum chamber forming the anode. The system also includes a power supply connected to the vacuum chamber, wherein the power supply is configured to generate an electric field within the vacuum chamber. The system further includes a cathode disposed within the vacuum chamber. The system also includes multiple permanent magnets configured to spin around in a vicinity of the cathode, wherein the magnets are further configured to apply a magnetic field in a direction transverse to the surface of the cathode and to the electric field resulting in a bum at a predetermined radius on the surface of the cathode. The system also includes at least one impeller coupled to the permanent magnets. The system further includes at least one cooling channel adapted to cool the cathode, and further configured to provide a cooling fluid to propel the impeller, wherein the impeller is configured to rotate the permanent magnets about a centerline axis of the cathode.

In accordance with another embodiment of the invention, a system for controlling cathodic arc discharge is provided. The system includes a vacuum chamber forming an anode. The system also includes a power supply connected to the vacuum chamber, wherein the power supply is configured to generate an electric field within the vacuum chamber. The system further includes a cathode disposed within the vacuum chamber. The cathode is configured to rotate about a centerline axis in the presence of a transverse magnetic field and disposed within the vacuum chamber. The system also includes a permanent magnet configured to apply the magnetic field transverse to the surface of the cathode and the electric field, resulting in a burn at a radius on the surface of the cathode, based upon strength of the magnetic field.

In accordance with another embodiment of the invention, a system for controlling cathodic arc discharge is provided. The system includes a vacuum chamber forming an anode. The system also includes a power supply connected to the vacuum chamber, wherein the power supply is configured to generate an electric field within the vacuum chamber. The system further includes a cathode disposed within the vacuum chamber. The system also includes at least one permanent magnet configured to rotate circumferentially around the cathode, wherein the magnet is further configured to apply a magnetic field in a direction parallel to a face of the cathode and to the electric field to burn the cathode at a predetermined radius on the face of the cathode.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic cross-sectional view of an exemplary system for controlling cathodic arc discharge employing a permanent magnet actuated in a translational direction in accordance with embodiments of the invention;

FIG. 2 is a schematic view of another exemplary system for controlling cathodic arc discharge employing multiple permanent magnets coupled to an impeller in accordance with embodiments of the invention;

FIG. 3 is a diagrammatic illustration of an exemplary cathode after erosion using the system in FIG. 2;

FIG. 4 is a schematic illustration of another exemplary system for controlling cathodic arc discharge employing a rotating cathode in accordance with embodiments of the invention; and

FIG. 5 is a schematic illustration of yet another exemplary system for controlling cathodic arc discharge, employing a rotating permanent magnet in accordance with embodiments of the invention.

### DETAILED DESCRIPTION

As discussed in detail below, embodiments of the invention include a system for controlling cathodic arc discharge employing mechanically manipulated permanent magnets. As used herein, the term “cathodic arc discharge” refers to an arc discharge produced under vacuum that vaporizes a material of the cathode that is further coated on a surface of a substrate or a workpiece.

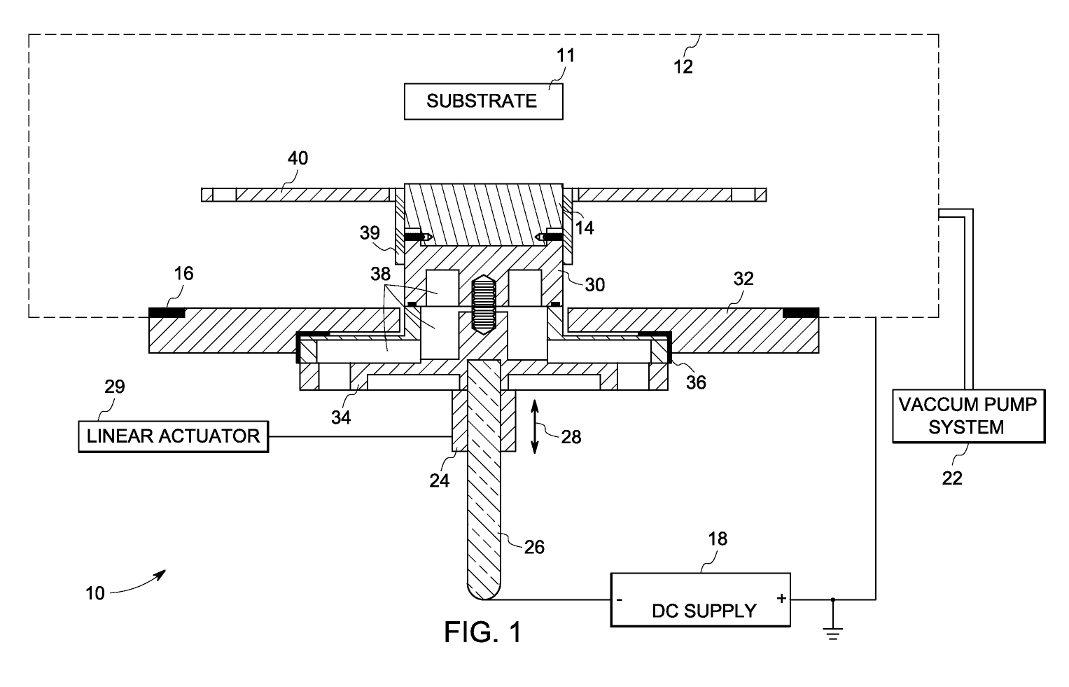

FIG. 1 is a schematic illustration of a system 10 for controlling a cathodic arc discharge used for coating a substrate or a workpiece 11. The system includes a vacuum chamber 12 having a cathode 14. The vacuum chamber 12 may also be referred to as an anode 12. In an exemplary embodiment, the cathode 14 is disk shaped. In another embodiment, the cathode 14 is cylindrical shaped. An electric power supply 18 coupled to the vacuum chamber produces an electric arc that is maintained upon a surface of the cathode 14 resulting in evaporation of material on the surface. In a non-limiting example, the strength of the electric arc is about 22 volts and about 85 amperes. The power supply 18 also contains an electric trigger source. In the illustrated embodiment, the power supply 18 is a DC power supply. In another embodiment, the DC power supply is a continuous DC power supply capable of producing greater than 60 amps at about 20 V for a total power output greater than about 1200 Watts. A vacuum pump system 22 maintains a desirable vacuum within the vacuum chamber 12. In a particular embodiment, the vacuum pump system 22 is of a generally conventional design including a pressure of at least about capable of at least 10⁻⁴ Torr.

At least one permanent magnet 24 is arranged axially about a current conductor 26 to the vacuum chamber 12 such as to actuate in a translational direction 28 inwards and outwards relative to the cathode 14 via a linear actuator 29. Non-limiting examples of the conductor 26 include aluminum, brass, copper and stainless steel. The magnet 24 actuates such that a magnetic field is applied in a direction perpendicular to a surface of the cathode 14. The magnetic field controls and directs a path of movement of the electric arc along a defined closed track such as, a circle of a predetermined radius, on the face of the cathode 14. In one embodiment, the predetermined radius includes a range between about 0.25 inch to about 1.125 inches. In a particular embodiment, the magnet 24 is actuated via a motor or a similar device. The interaction of field generated by the electric arc and the magnetic field provided by the permanent magnet 24 will cause a cathode spot to be controlled in a more predictable manner.

A holder 30 attaches the cathode 14 to a large evaporator plate 32 and a small evaporator plate 34. Furthermore, the large evaporator plate 32 and the small evaporator plate 34 are separated by electrical insulation 36. Multiple cooling channels 38 pass through the large evaporator plate 32 and the small evaporator plate 34 that enable cooling of the cathode 14, thus maintaining a desirable temperature of the cathode 14. In one embodiment, the cooling channels 38 provide a cooling fluid such as, but not limited to, water to the cathode 14 and the vacuum chamber 12. A sleeve 39 is employed as an insulating layer between the cathode 14 and a ground shield 40.

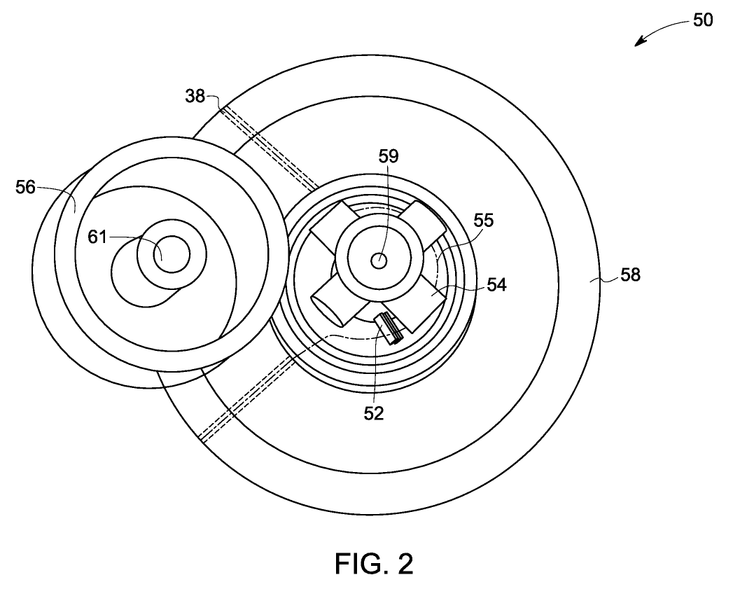

FIG. 2 is a schematic illustration of another exemplary system 50 for controlling a cathodic arc discharge. The system 50 includes at least one impeller 52 coupled to multiple permanent magnets 54 that spin around in a vicinity of the cathode 14 (FIG. 1). A cooling fluid 55 through the cooling channel 38, as referenced in FIG. 1, propels the impeller 52 that further rotates the permanent magnets 54 about an axis resulting in a magnetic field in a direction parallel to a surface of the cathode 14. Non-limiting examples of the cooling fluid include water and ethylene glycol. In another embodiment, a motor propels the impeller 52. The rotation of the magnets 54 controls and directs a path of movement of the arc along a defined closed track such as a circle of a predetermined radius on the face of the cathode 14. In one embodiment, the predetermined radius includes a range between about 0.75 inch to about 0.875 inch. A holder 56 (shown inverted) for the cathode 14 is disposed on an evaporator plate 58 covering the permanent magnets 54. A stud 59 on the evaporator plate 58 holds the holder 56 via a threaded hole 61 on the holder with a seal to contain the cooling fluid.

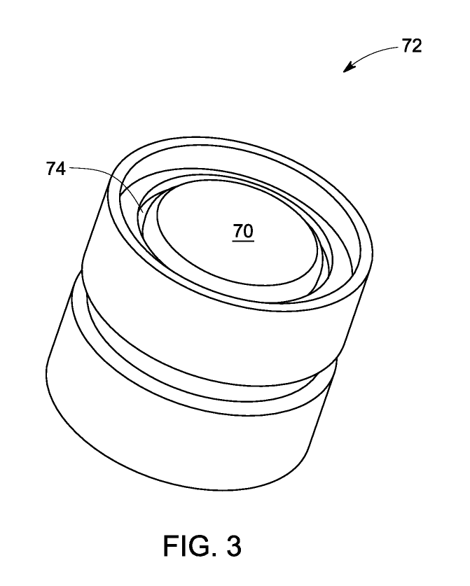

FIG. 3 is a diagrammatic illustration of an exemplary surface 70 of a cathode 72 employing the aforementioned system 50. The surface 70 shows a uniformity in erosion of the cathode 72 due to steering of an electric arc around the cathode 72. Specifically, steering the arc around a circumference of the cathode 72 results in uniform circumferential erosion as illustrated by track 74.

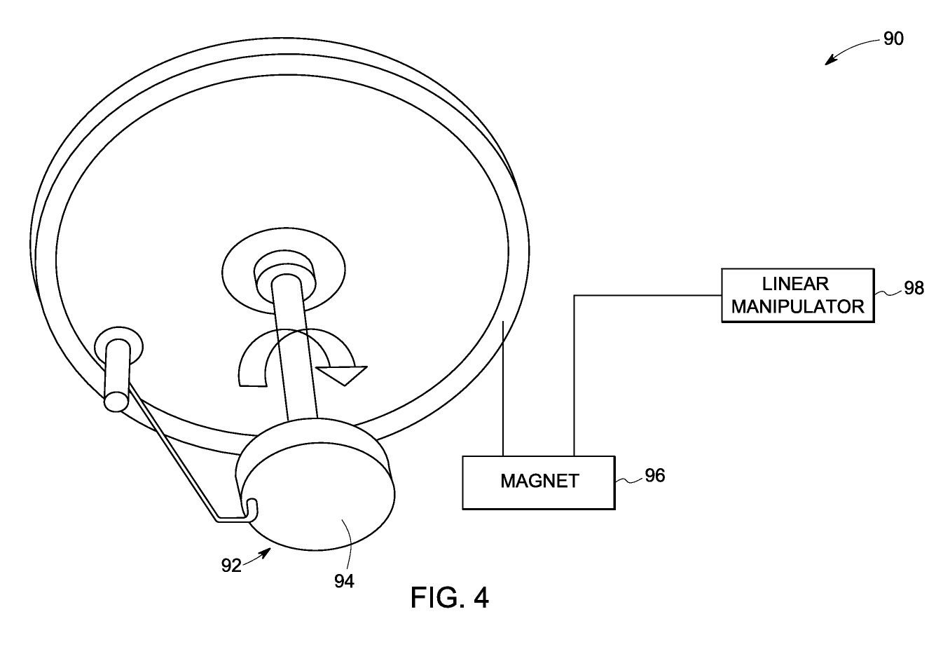

FIG. 4 is a schematic illustration of another exemplary system 90 for controlling a cathodic arc discharge. The system 90 includes a cathode 92 that rotates about its own axis transverse to a surface 94 of the cathode 92 in a vacuum chamber 12 (FIG. 1). In a non-limiting example, a material for the cathode 92 may include graphite. A permanent magnet 96 applies a magnetic field transverse to the surface 94 of the cathode resulting in a uniform movement of an electric arc on the cathode 92. In an exemplary embodiment, a motor drives the cathode 92. The rotation ensures a relative motion of the cathode 92 with respect to the stationary permanent magnet 96, allowing the magnetic field to control and direct a path of movement of the arc along a defined closed track such as a circle of a predetermined radius on the surface 94 of the cathode 92. In a particular embodiment, the permanent magnet 96 is coupled to a linear manipulator 98 or a similar device to enable translational motion inwards and outwards relative to the cathode 92. In another embodiment, the linear manipulator 98 includes multiple motorized translation stages and rack-and-pinion linear motion drives or similar devices.

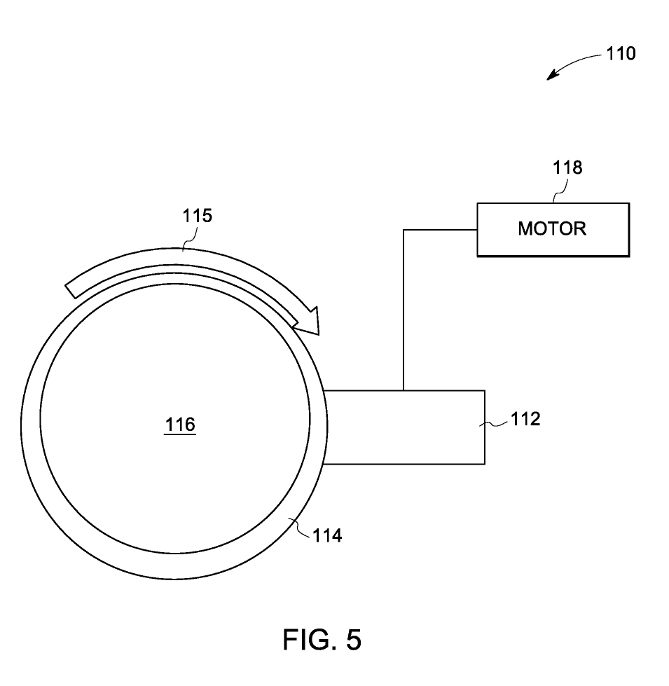

FIG. 5 is a schematic illustration of yet another exemplary system 110 for controlling a cathodic arc discharge. The system 110 includes at least one permanent magnet 112 rotating around a circumference of a stationary cathode 114 in a direction 115. In a particular embodiment, the magnet 112 is driven by a motor 118. The relative motion of the permanent magnet 112 with respect to the cathode 114 induces a magnetic field parallel to a surface 116 of the cathode 114. The magnetic field controls direct a path of movement of the arc along a defined closed track such as a circle of a predetermined radius on the surface 114 of the cathode 112.

The various embodiments of a system for controlling cathodic arc discharge described above thus provide an efficient and convenient means for steering an electric arc around a cathode. These techniques and systems also allow for uniform deposition of coating on a substrate or a workpiece. In addition, velocity of the arc around a circumference of the cathode, being a function of strength of magnetic field and amount of current supplied, may be manipulated by changing either the magnetic field or the current or both. Further, the system employs a cost-effective cathode, wherein the cathode can be cut, for example, from a cylindrical casting. Such a cathode requires minimal expensive machining, thereby reducing cost of the cathode and overall coating process. Moreover, a circumferentially uniform erosion of the cathode enables maximizing the life of the cathode prior to a replacement.

Of course, it is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

Furthermore, the skilled artisan will recognize the interchangeability of various features from different embodiments. For example, the use of an example of a disk-shaped cathode described with respect to one embodiment can be adapted for use in a system employing a rack-and-pinion linear motion drive described with respect to another. Similarly, the various features described, as well as other known equivalents for each feature, can be mixed and matched by one of ordinary skill in this art to construct additional systems and techniques in accordance with principles of this disclosure.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A system for controlling cathodic arc discharge comprising:
a vacuum chamber forming an anode;
a power supply connected to the vacuum chamber, the power supply configured to generate an electric field within the vacuum chamber;
a cathode disposed within the vacuum chamber;
at least one permanent magnet configured to actuate in a translational direction inwards and outwards of the cathode, the magnet further configured to apply a magnetic field in a direction perpendicular to a face of the cathode and to the electric field to burn the cathode at a predetermined radius on the face of the cathode.

2. The system of claim 1, further comprising a motor configured to actuate the at least one permanent magnet.

3. The system of claim 1, further comprising at least one cooling channel configured to provide a cooling fluid to the cathode and the vacuum chamber.

4. The system of claim 1, wherein the cathode comprises a disk-shaped or cylindrical cathode.

5. The system of claim 1, wherein the power supply comprises a DC power supply.

6. The system of claim 1, further comprising a conductor coupled to the permanent magnet, the conductor configured to conduct electric current from the vacuum chamber.

7. The system of claim 6, wherein the conductor comprises aluminum, brass, copper or stainless steel.

8. The system of claim 1, wherein the predetermined radius comprises a radius between about 0.25 inches to about 1.125 inches.

9. A system for controlling cathode arc discharge comprising:
a vacuum chamber forming an anode;
a power supply connected to the vacuum chamber, the power supply configured to generate an electric field within the vacuum chamber;
a cathode disposed within the vacuum chamber;
a plurality of permanent magnets configured to spin around in a vicinity of the cathode, the magnets further configured to apply a magnetic field in a direction transverse to a surface of the cathode and to the electric field resulting in a burn at a predetermined radius on the surface of the cathode;
at least one impeller coupled to the permanent magnets; and
at least one cooling channel adapted to cool the cathode, the cooling channel further configured to provide a cooling fluid to propel the impeller, wherein the impeller is configured to rotate the permanent magnets about a centerline axis of the cathode.

10. The system of claim 9, further comprising a motor configured to drive the impeller.

11. The system of claim 9, wherein the cooling fluid comprises water or ethylene glycol.

12. The system of claim 9, wherein the power supply comprises a DC power supply.

13. The system of claim 9, wherein the predetermined radius comprises a radius between about 0.75 inches to about 0.875 inches.

14. A system for controlling cathode arc coating comprising:
a vacuum chamber forming an anode;
a power supply connected to the vacuum chamber, the power supply configured to generate an electric field within the vacuum chamber;
a cathode configured to rotate about a centerline axis subjected to a transverse magnetic field and disposed within the vacuum chamber; and
a permanent magnet configured to apply the magnetic field transverse to the surface of the cathode and the electric field resulting in a burn at a radius on the surface of the cathode, based upon strength of the magnetic field.

15. The system of claim 14, further comprising a motor device configured to rotate the cathode.

16. The system of claim 14, wherein the power supply comprises a DC power supply.

17. The system of claim 14, further comprising a linear manipulator configured to move the permanent magnet in a translational direction inwards and outwards relative to the cathode.

18. The system of claim 17, wherein the linear manipulator is selected from a group consisting of motorized translation stages, rack-and-pinion linear motion drives and combinations thereof.

19. A system for controlling cathodic arc discharge comprising:
a vacuum chamber forming an anode;
a power supply connected to the vacuum chamber, the power supply configured to generate an electric field within the vacuum chamber;
a cathode disposed within the vacuum chamber;
at least one permanent magnet configured to rotate circumferentially around the cathode, the magnet further configured to apply a magnetic field in a direction parallel to a face of the cathode and to the electric field to burn the cathode at a predetermined radius on the face of the cathode.

20. The system of claim 19, further comprising a motor configured to actuate the at least one permanent magnet.
